(19) United States
(12) Patent Application Publication
(10) Pub. No.: US 2004/0033689 A1
(43) Pub. Date: Feb. 19, 2004

(54) Method for defining a dummy pattern around an alignment mark on a wafer

(76) Inventors: Lien-Che Ho, Hsinchu (TW); Ting-Chang Lin, Hsinchu (TW); Mao-I Ting, Hsinchu (TW)

Correspondence Address: BIRCH STEWART KOLASCH & BIRCH, PO BOX 747, FALLS CHURCH, VA, 22040-0747, US

(21) Appl. No.: 10/315,083

(22) Filed: Dec. 10, 2002

(30) Foreign Application Priority Data
Aug. 14, 2002 (TW) 091118284

(51) Int. Cl. H01L 23/544; H01L 21/44

(52) U.S. Cl. 438/687

(57) ABSTRACT

A method for defining a dummy pattern around an alignment mark on a wafer. First, a wafer having an alignment area with an alignment mark is provided. Thereafter, lithography is performed on the wafer by a mask to define a first dummy pattern around the alignment mark in the alignment area. The mask includes a first dummy pattern area, with a first pattern to mask the alignment mark and a second pattern to define the first dummy pattern, and a second dummy pattern area, with a third pattern to define a second dummy pattern around the first dummy pattern.

### BACKGROUND OF THE INVENTION

1. Field of the Invention

The present invention relates in general to a method for defining a dummy pattern around an alignment mark on a wafer. In addition, the invention further provides a mask for defining the dummy pattern and a wafer with the dummy pattern to prevent silicon nitride residue due to chemical mechanical polishing (CMP).

2. Description of the Related Art

As is well known in the art, the position of the alignment mark (AM) on the wafer is commonly sensed by means of a laser beam. The laser beam in the stepper is bounced off the alignment mark to create a pattern of laser light. The diffraction from the mark is reflected back to sending devices in the stepper and is used as a signal to measure the exact position of the alignment mark.

In general, AMs formed in a wafer are subjected to the same process steps that the rest of the wafer experiences. The steps include deposition of conductors, insulators, etching of the same, polishing and so on. Before and after each one of these steps, the AM must preserve its exact dimensions and be visible to the observing beam, such as the laser beam, so that alignment of various layers with respect to the mark will always be precisely repeatable.

However, as chemical mechanic polishing (CMP) is introduced in shallow trench isolation (STI), a silicon nitride (SiN) layer (a mask layer for STI) deposited around AM in the alignment area of the wafer creates a large blank area (non-pattern area) and causes SiN residue after finishing CMP for STI. In order to solve this problem, a conventional approach is to form a dummy pattern around the alignment mark in the alignment area of the wafer, thereby reducing the non-pattern area to prevent particle contamination due to SiN residue as mentioned above. In conventional process, the dummy pattern is formed using a shield to cover a part of the product pattern formed in the mask, thereby transferring and piecing up the pattern into the alignment area of the wafer.

However, the dummy pattern cannot completely occupy the alignment area in this approach, thus the non-pattern area remains. The remaining non-pattern area still causes SiN residue after finishing CMP for STI. Accordingly, particle contamination cannot be prevented in the subsequent process. In addition, another approach to eliminate the SiN residue is to over polish the silicon nitride layer during CMP. Unfortunately, this approach causes the AM to be damaged, thereby failing its alignment function.

### SUMMARY OF THE INVENTION

Accordingly, an object of the invention is to provide a novel mask for defining a dummy pattern around an alignment mark on a wafer instead of the conventional mask for defining the dummy pattern.

Another object of the invention is to provide a method for defining a dummy pattern around an alignment mark on a wafer to prevent particle contamination after chemical mechanical polishing for shallow trench isolation.

One aspect of the invention provides a mask for defining a dummy pattern around an alignment mark on a wafer. The mask includes a first dummy pattern area, which has a first pattern to mask the alignment mark and a second pattern to define a first dummy pattern around the alignment mark, and a second dummy pattern area, which has a third pattern to define a second pattern around the first dummy pattern. Moreover, the second and third patterns are composed of a plurality of island structures, line structures, island and line structures, holes, line openings, or holes and line openings.

Another aspect of the invention provides a method for defining a dummy pattern around an alignment mark on a wafer. First, a wafer having an alignment area, with an alignment mark disposed therein, is provided. Thereafter, lithography is performed on the wafer by a mask to define a first dummy pattern around the alignment mark in the alignment area. The mask includes a first dummy pattern area, which has a first pattern to mask the alignment mark and a second pattern to define the first dummy pattern, and a second dummy pattern area, which has a third pattern to define a second dummy pattern around the first dummy pattern. Moreover, the second and third patterns are composed of a plurality of island structures, line structures, island and line structures, holes, line openings, or holes and line openings.

### BRIEF DESCRIPTION OF THE DRAWINGS

The present invention can be more fully understood by reading the subsequent detailed description in conjunction with the examples and references made to the accompanying drawings, wherein:

FIG. 1 is a plane view of a mask for defining a dummy pattern around an alignment mark on a wafer according to the present invention.

FIG. 2a is an enlarged plane view of the first dummy pattern area in FIG. 1.

FIG. 2b is an enlarged plane view of another example of the first dummy pattern area in FIG. 1.

FIG. 2c is an enlarged plane view of another example of the first dummy pattern area in FIG. 1.

FIG. 2d is an enlarged plane view of another example of the first dummy pattern area in FIG. 1.

FIG. 3a is an enlarged plane view of the second dummy pattern area in FIG. 1.

FIG. 3b is an enlarged plane view of another example of the second dummy pattern area in FIG. 1.

FIG. 3c is an enlarged plane view of another example of the second dummy pattern area in FIG. 1.

FIG. 3d is an enlarged plane view of another example of the second dummy pattern area in FIG. 1.

FIG. 4 is a plane view of a wafer with an alignment mark after performing STI according to the invention.

FIG. 5 is an enlarged plane view of the alignment area in FIG. 4.

FIG. 6 is an enlarged plane view of another example of the alignment area in FIG. 4.

FIGS. 7a through 7f are cross-sections showing a method for defining a dummy pattern around an alignment mark on a wafer according to the present invention.

### DETAILED DESCRIPTION OF THE INVENTION

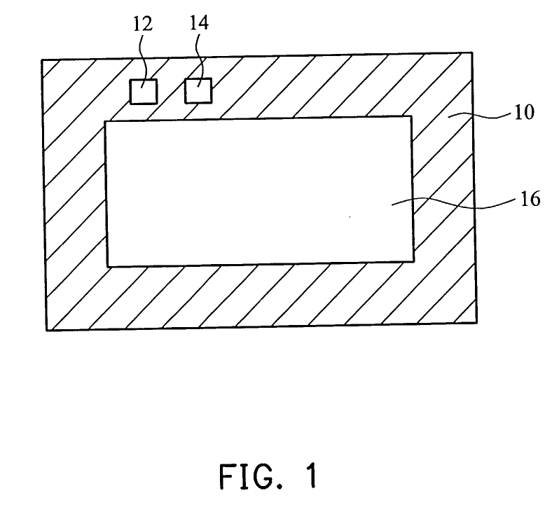

FIG. 1 is a plane view of a mask for defining a dummy pattern around an alignment mark (AM) on a wafer according to the present invention. In FIG. 1, the mask 10 has a first dummy pattern area 12, a second dummy pattern area 14, and a product pattern area 16. In this invention, the mask 10 may be without the product pattern area 16. That is, the mask 10 is only used for defining a dummy pattern.

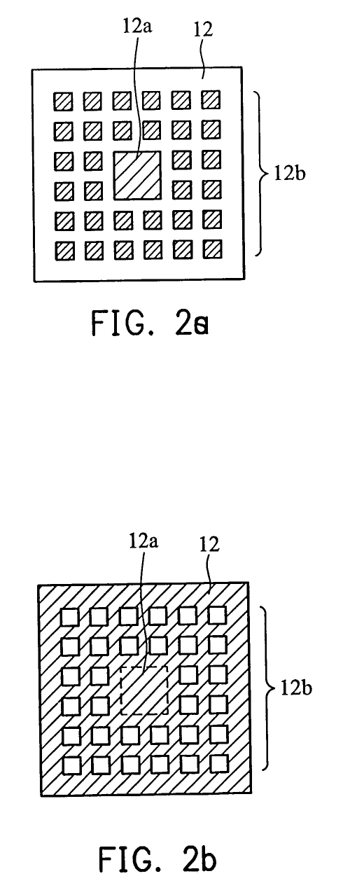

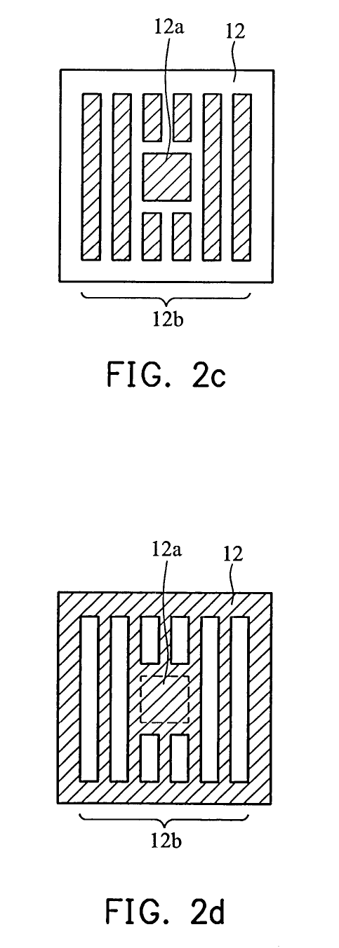

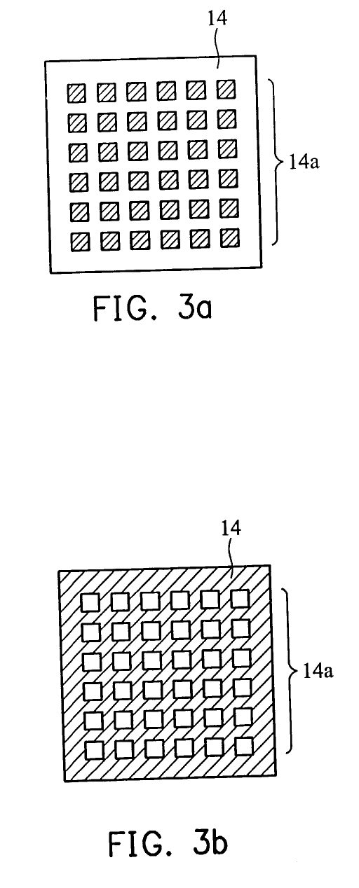

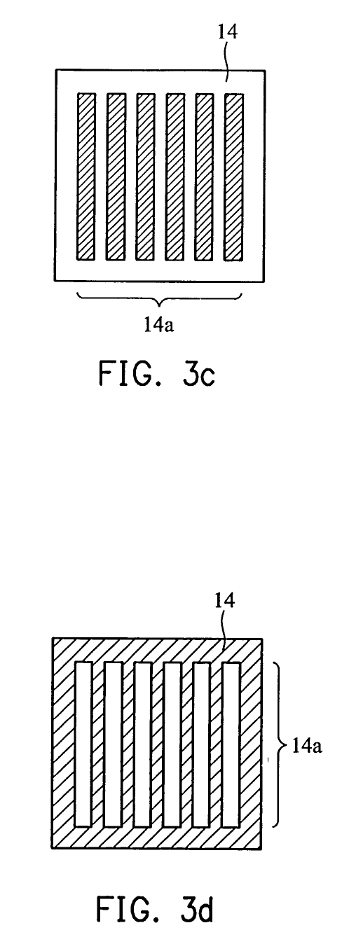

FIG. 2a is an enlarged plane view showing the first dummy pattern area 12 in FIG. 1. In FIG. 2a, the first dummy pattern area 12 has a first pattern 12a and a second pattern 12b. The first pattern 12a is used for masking the AM of the wafer (not shown), and its dimension is substantially equal to the AM. The second pattern 12b is used for defining the first dummy pattern (not shown) around the AM. In this invention, the second pattern 12b is composed of a plurality of island structures, with the interval between each based on the dimensions of the first pattern 12a to match the edge levels of the island structure and the first pattern 12a. Moreover, the second pattern 12b can be composed of a plurality of holes. Also, the interval between each of these holes is based on the dimensions of the first pattern 12a, as shown in FIG. 2b.

FIG. 2c is an enlarged plane view showing another example of the first dummy pattern area 12 in FIG. 1. In FIG. 2c, the second pattern 12b is composed of a plurality of line structures, with the interval between each based on the dimensions of the first pattern 12a to match the edge levels of the line structure and the first pattern 12a. Moreover, the second pattern 12b can be composed of a plurality of line openings. Also, the interval between each of the line openings is based on the dimensions of the first pattern 12a, as shown in FIG. 2d.

In addition, the second pattern 12b can be composed of a plurality of island and line structures (not shown) or a plurality of holes and line openings (not shown).

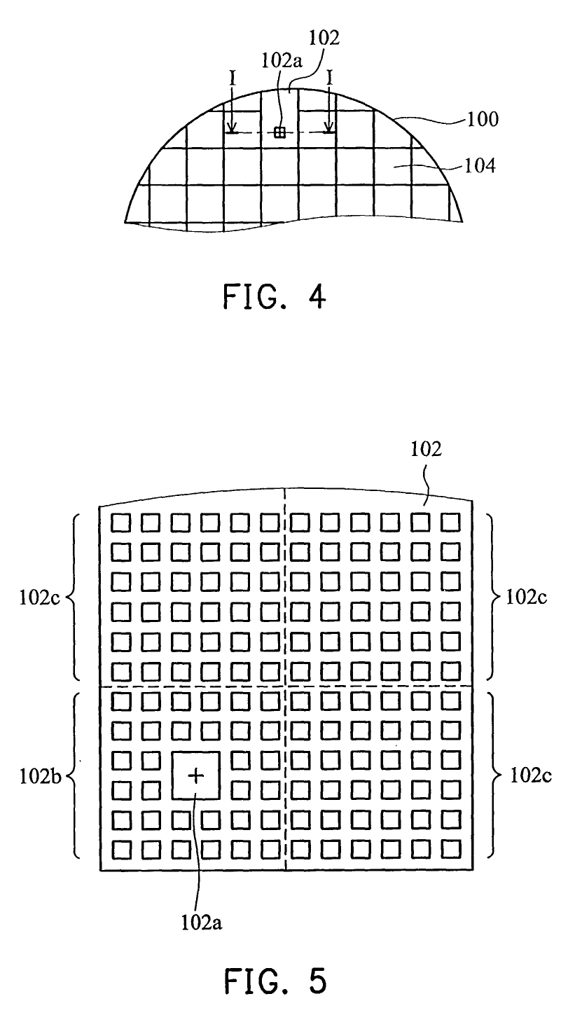

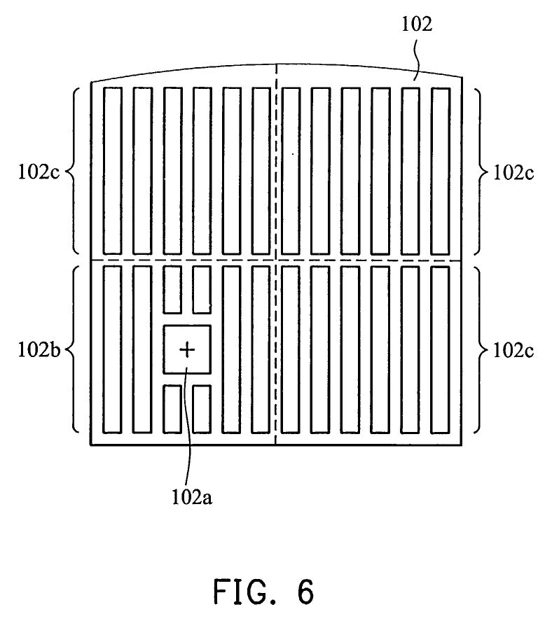

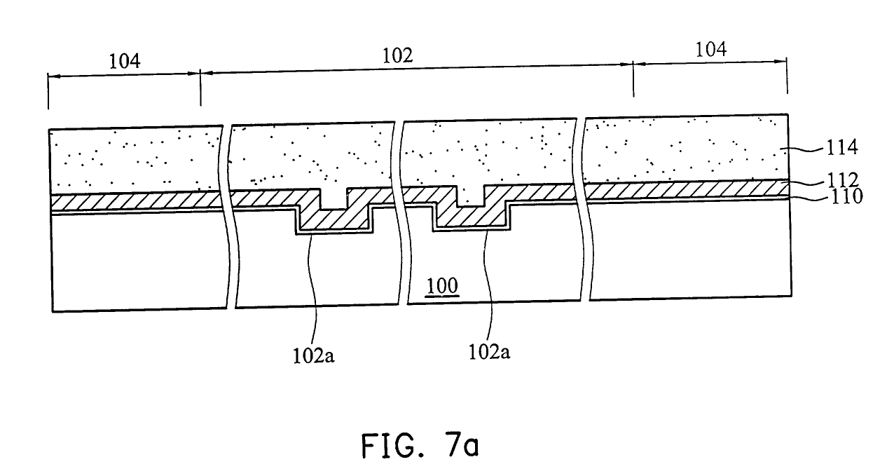

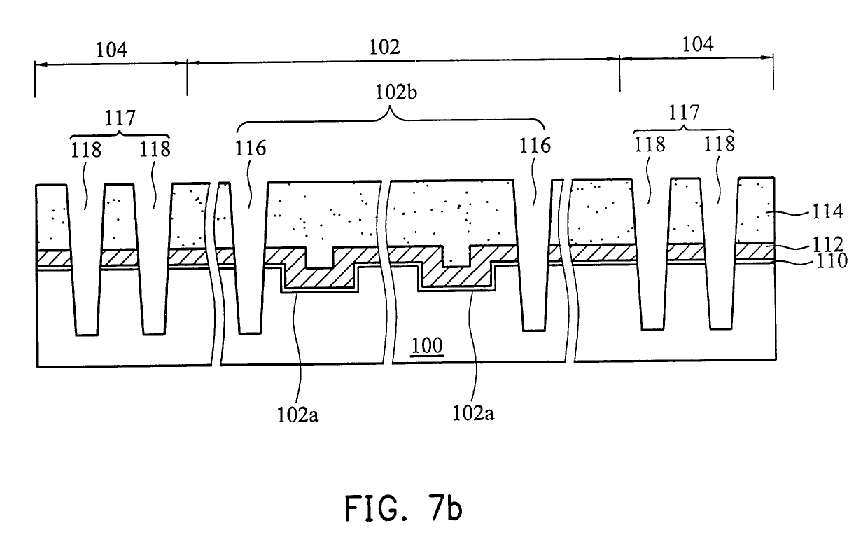

FIG. 3a is an enlarged plane view of the second dummy pattern area 14 in FIG. 1. In FIG. 3a, the second dummy pattern area 14 has a third pattern 14a, used for defining a second dummy pattern (not shown) around the first dummy pattern, and is composed of a plurality of island structures. In this invention, the third pattern 14a can be a plurality of holes (as shown in FIG. 3b), line structures (as shown in FIG. 3c), or line openings (as shown in FIG. 3d). Also, the third pattern 14a can be composed of a plurality of island and line structures (not shown) or composed of a plurality of holes and line openings (not shown).

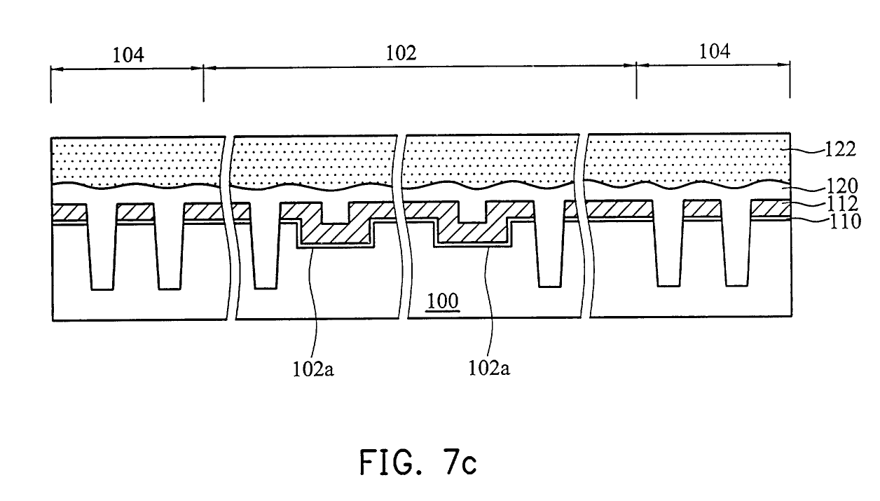

FIG. 4 is a plane view of a wafer with an AM after shallow trench isolation (STI) according to the invention. In FIG. 4, the wafer includes a substrate 100 having an alignment area 102 and a product area 104. An AM 102a and a dummy pattern (not shown) having repeated structures around the AM 102a are disposed in the alignment area 102. In this invention, the dummy pattern can be formed by the mask 10 in FIG. 1.

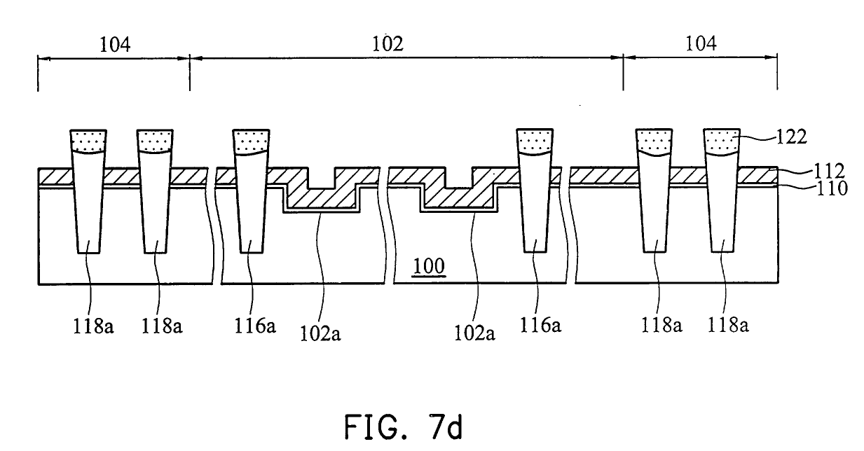

FIG. 5 is an enlarged plane view of the alignment area 102 in FIG. 4. In FIG. 5, the first dummy pattern 102b in the alignment area 102 is formed by the first dummy pattern area 12 of the mask 10 in FIG. 1, and can be composed of a plurality of holes or island structures. It is noted that when the first dummy pattern 102b cannot completely occupy the alignment area 102, the second dummy pattern 102c can be repeatedly formed around the first dummy pattern 102b by the second dummy pattern area 14 of the mask 10 in FIG. 1. Also, the second dummy pattern 102c can be composed of a plurality of holes or island structures.

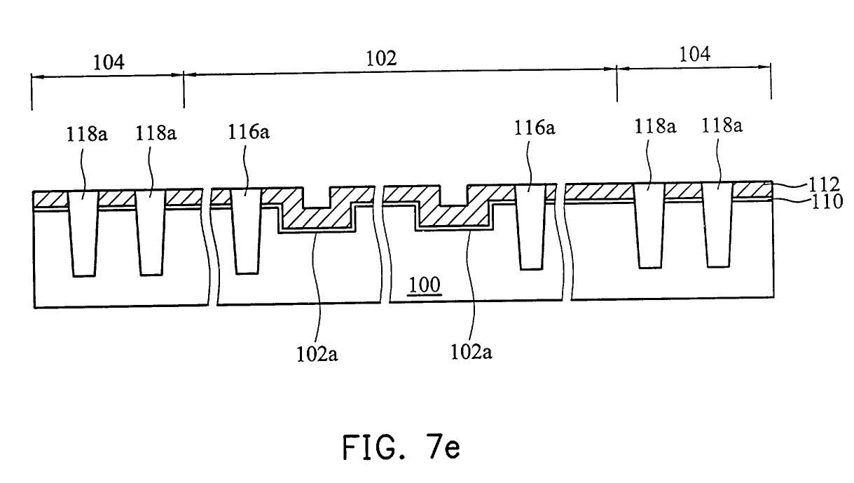

FIG. 6 is an enlarged plane view of another example of the alignment area in FIG. 4. In FIG. 6, the first dummy pattern 102b and the second dummy pattern 102c can be composed of a plurality of line structures or line openings. Also, when the first dummy pattern 102b cannot completely occupy the alignment area 102, the second dummy pattern 102c can be repeatedly formed around the first dummy pattern 102b by the second dummy pattern area 14 of the mask 10 in FIG. 1.

It is noted that the first dummy pattern 102b and the second dummy pattern 102c can be composed of a plurality of island and line structures or composed of a plurality of holes and line openings.

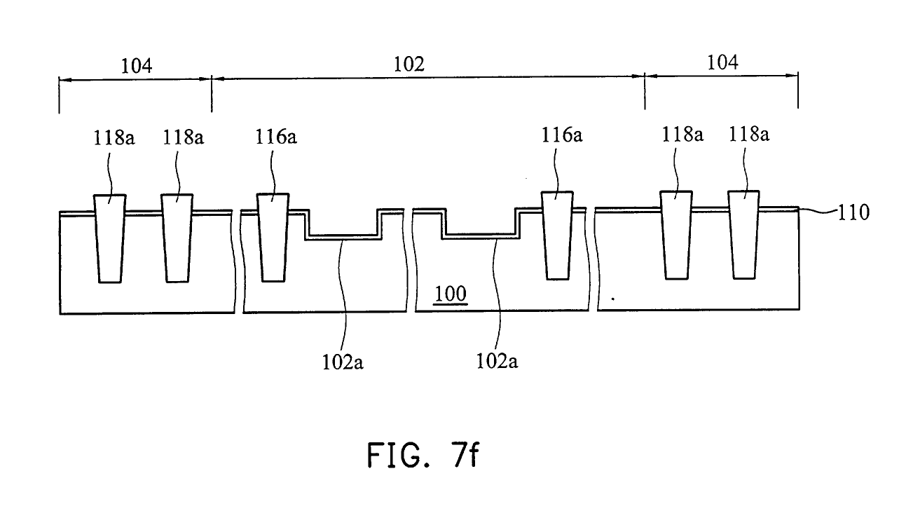

FIGS. 7a through 7f are cross-sections showing a method for defining a dummy pattern around an alignment mark on a wafer according to the present invention. Moreover, FIG. 7f is a cross-section along I-I line in FIG. 4.

First, in FIG. 7a, a substrate 100, such as a silicon wafer, having an alignment area 102 and a product area 104, is provided, with an AM 102a disposed in the alignment area 102. Moreover, a pad oxide layer 110, a silicon nitride layer 112, and a photoresist layer 114 are sequentially deposited on the wafer 100 for fabricating device isolation by STI.

Next, in FIG. 7b, lithography is performed on the photoresist layer 114 by the first dummy pattern area 12 of the mask 10 shown in FIG. 1, and the silicon nitride layer 112, pad oxide layer 110, and wafer 100 are etched to form a first dummy pattern 102b around the AM 102a in the alignment area 102 and a product pattern 117 in the product area 104. The first dummy pattern 102b is composed of a plurality of holes 116 or line openings 116. In this invention, also, the first dummy pattern 102b can be composed of a plurality of holes and line openings, island structures, line structures, or island and line structures. In addition, the openings 118 of the product pattern 117 serve as isolation trench for devices.

As mentioned above, when the alignment area 102 has a larger area, the first dummy pattern 102b cannot completely occupy the alignment area 102 and results in non-patterned areas occurring in the alignment area 102. Accordingly, a second dummy pattern (not shown) can be repeatedly defined around the first dummy pattern 102b to eliminate the non-patterned areas using the second dummy pattern area 14 of the mask 10 when lithography (for defining the first dummy pattern 102b) is performed. Also, the second dummy pattern can be composed of a plurality of holes, line openings, holes and line openings, island structures, line structures, or island and line structures. The first dummy pattern 102b and the second dummy pattern eliminate the non-patterned areas to prevent proximity effect during the subsequent CMP.

Next, in FIG. 7c, after the photoresist layer 114 is removed, an oxide layer 120, such as high-density plasma (HDP) oxides is formed on the silicon nitride layer 112 and fills the openings 116, 118. Thereafter, a photoresist layer 122 is coated on the oxide layer 120.

Next, in FIG. 7d, reverse tone lithography is performed on the photoresist layer 122 to form openings (not shown) over the silicon nitride layer 112 covered by the oxide layer 120. Subsequently, the oxide layer 120 over the silicon nitride layer 112 is etched using the photoresist layer 122 as a mask to expose the silicon nitride layer 112. The oxides 120 filling in the openings 116, 118 remain and serve as STI structures 116a, 118a.

Next, in FIG. 7e, after the photoresist layer 122 is removed, CMP is performed on the STI structures 116a, 118a using the silicon nitride layer 112 as a polish stop layer. Finally, in FIG. 7f, the silicon nitride layer 112 is removed. The method of removing the silicon nitride layer 112, is, for example, soaking with hot H₃PO₄. In this invention, since the first dummy pattern 102b is formed around the AM 102a in the alignment area 102, even if the second pattern is repeatedly formed therein, there are no non-pattern areas in the alignment area 102. Accordingly, there is no residual oxide layer 120 in the alignment area 102 from proximity effect. That is, the invention prevents the silicon nitride residue during subsequent processes such as CMP and wet etching for removing silicon nitride layer 112, avoiding particle contamination, and thus increasing the yield of the devices.

The foregoing description has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A mask for defining a dummy pattern around an alignment mark on a wafer, comprising:
a first dummy pattern area having a first pattern to mask the alignment mark and a second pattern to define a first dummy pattern around the alignment mark.

2. The mask as claimed in claim 1, further comprising a second dummy pattern area having a third pattern to define a second dummy pattern around the first dummy pattern.

3. The mask as claimed in claim 2, wherein the third pattern is composed of a plurality of island structures, line structures, or island and line structures.

4. The mask as claimed in claim 2, wherein the third pattern is composed of a plurality of holes, line openings, or holes and line openings.

5. The mask as claimed in claim 1, further comprising a product pattern area to define a product pattern in the wafer.

6. The mask as claimed in claim 1, wherein the second pattern is composed of a plurality of island structures, line structures, or island and line structures.

7. The mask as claimed in claim 1, wherein the second pattern is composed of a plurality of holes, line openings, or holes and line openings.

8. A method for defining a dummy pattern around an alignment mark on a wafer, comprising the steps of:
providing a wafer having an alignment area wherein the alignment mark is disposed; and
performing lithography by a mask to define a first dummy pattern around the alignment mark in the alignment area, wherein the mask includes a first dummy pattern area having a first pattern and a second pattern.

9. The method as claimed in claim 8, wherein, after defining the first dummy pattern, reverse tone lithography is further performed.

10. The method as claimed in claim 8, wherein the first pattern is used for masking the alignment mark.

11. The method as claimed in claim 8, wherein the second pattern is used for defining the first dummy pattern.

12. The method as claimed in claim 8, wherein the second pattern is composed of a plurality of island structures, line structures, or island and line structures.

13. The method as claimed in claim 8, wherein the second pattern is composed of a plurality of holes, line openings, or holes and line openings.

14. The method as claimed in claim 8, wherein the mask further comprises a second dummy pattern area having a third pattern.

15. The method as claimed in claim 14, further comprising formation of a second dummy pattern around the first dummy pattern by the mask.

16. The method as claimed in claim 14, wherein the third pattern is composed of a plurality of island structures, line structures, or island and line structures.

17. The method as claimed in claim 14, wherein the third pattern is composed of a plurality of holes, line openings, or holes and line openings.

18. The method as claimed in claim 8, wherein the mask substrate further comprises a product pattern area to define a product pattern in the wafer.

19. A wafer with an alignment mark, comprising:
a semiconductor substrate having an alignment area;
an alignment mark disposed in the alignment area; and
a dummy pattern disposed in the alignment area and around the alignment mark, composed of repeated structures.

20. The wafer as claimed in claim 19, wherein the dummy pattern is composed of a plurality of island structures, line structures, or island and line structures.

21. The wafer as claimed in claim 19, wherein the dummy pattern is composed of a plurality of holes, line openings, or holes and line openings.
